(19) United States
(12) Patent Application Publication
(10) Pub. No.: US 2016/0131603 A1
(43) Pub. Date: May 12, 2016

(54) METHODS OF PREDICTING OF CHEMICAL PROPERTIES FROM SPECTROSCOPIC DATA

(71) Applicant: THE GEORGE WASHINGTON UNIVERSITY, A CONGRESSIONALLY CHARTERED NOT-FOR-PROFIT, Washington, DC (US)

(72) Inventors: Farid VAN DER MEI, Washington, DC (US); Adelina VOUTCHKOVA-KOSTAL, Washington, DC (US)

(73) Assignee: The George Washington University a Congressionally Chartered Not-for-Profit Corporation, Washington, DC (US)

(21) Appl. No.: 14/898,066

(22) PCT Filed: Jun. 17, 2014
(86) PCT No.: PCT/US14/42784

§ 371 Date: Dec. 11, 2015

Related U.S. Application Data
(60) Provisional application No. 61/836,430, filed on Jun. 18, 2013.

(51) Int. Cl. G01N 24/08; G01R 33/46; G01R 33/485

(52) U.S. Cl. CPC G01N 24/08; G01R 33/485; G01R 33/46

(57) ABSTRACT

A method of predicting of chemical properties from spectroscopic data is described. The chemical property can be, for example, octanol-water partition coefficient (logP), skin permeability (log K,), or other biologically or ecologically relevant property, such as oral bioavailability, skin sensitization, acute aquatic toxicity, chronic aquatic toxicity, aquatic bioaccumulation, or mutagenicity. The spectroscopic data can be experimental or predicted NMR data, e.g., experimental or predicted ¹H-NMR or ¹³C-NMR data.

### CLAIM OF PRIORITY

This application claims priority to U.S. provisional application No. 61/836,430, filed Jun. 18, 2013, which is incorporated by reference in its entirety.

### BACKGROUND

The octanol-water partition coefficient (logP) is a widely used physicochemical property in medicinal chemistry and toxicology. Medicinal chemists routinely use logP to estimate the oral and skin bioavailability of drug candidates. Ecotoxicologists and regulators use logP to model acute and chronic toxicity to aquatic species and potential for bio accumulation. Rules of thumb for designing minimally toxic chemicals to aquatic species are also based on logP, among other parameters, and suggest that compounds with logP less than 2 are more likely to be safe to aquatic species. The octanol-water partition coefficient is thus a ubiquitous property that is routinely determined by chemists, toxicologists and regulators, and streamlined methods for its determination are desirable.

Furthermore, the skin permeability of chemicals (log Kp) is widely used by medicinal and cosmetic chemists as well as toxicologists. Medicinal chemists must consider the skin permeability rate of dermal API's in order to deliver the desired dose. For cosmetics chemists, the control of skin peilneation is important in formulating personal care products. Toxicologists consider the skin as a barrier that protects the body from chemical attack, and must take skin permeability into account when carrying out chemical risk assessments or alternatives assessments. Improved methods for determination of skin permeability are also desirable.

### SUMMARY

In one aspect, a method of predicting a chemical property of a compound includes: measuring and/or predicting a plurality of NMR resonances of the compound; defining at least one molecular descriptor of the compound based on the measured and/or predicted resonances; and calculating a predicted value of the chemical property based on the at least one molecular descriptor.

In another aspect, a method of building a model for predicting a chemical property includes: (a) measuring and/or predicting a plurality of NMR resonances of a plurality of compounds belonging to a training set of compounds; (b) defining at least one molecular descriptor of each compound belonging to the training set based on the measured and/or predicted resonances of that compound; (c) calculating a predicted value of the chemical property for each compound belonging to the training set based on the at least one molecular descriptor; (d) for each compound belonging to the training set, comparing the predicted values of the chemical property to experimentally determined values of the chemical property, and determining a correlation coefficient between the predicted values of the chemical property to experimentally determined values of the chemical property; (e) optionally redefining the at least one molecular descriptor; and (f) repeating steps (b)-(e) to identify a set of molecular descriptors providing a desired correlation coefficient.

In another aspect, a computer-readable medium for predicting a chemical property of a compound, includes non-transitory computer-executable code which, when executed by a computer, causes the computer to: receive a plurality of NMR resonances of the compound; define at least one molecular descriptor of the compound based on the resonances; and calculate a predicted value of the chemical property based on the at least one molecular descriptor.

In another aspect, a system for predicting a chemical property of a compound, includes: an NMR spectrometer including: a magnet for generating a static homogeneous magnetic field; and a probe including RF coils disposed within said homogeneous magnetic field, wherein the RF coils are configured to transmit a radio frequency magnetic pulse to a sample including the compound, and wherein the RF coils are configured to measure a plurality of NMR resonances from the compound; and a data processor operably connected to the NMR spectrometer, wherein said data processor is configured to: receive a plurality of NMR resonances of the compound; define at least one molecular descriptor of the compound based on the resonances; and calculate a predicted value of the chemical property based on the at least one molecular descriptor.

Other features will be apparent from the following description, the drawings, and the claims.

### BRIEF DESCRIPTION OF THE DRAWINGS

FIG. 1 is a schematic illustration depicting some ¹H-NMR spectroscopic parameters that can be used to predict logP.

FIG. 2 is a schematic depiction of an NMR system including an NMR spectrometer and a computer running NMR control and processing software.

FIG. 3 is a graph illustrating the number of spectral intervals vs. model accuracy (R²) for two multivariate models. Solid circles (a) are for an initial model that did not include a descriptor for peak breadth; crosses (b) represent an improved model that included descriptors for three broad peaks.

FIG. 4 illustrates the chemical structures of compounds in a training set.

FIG. 5 is a graph showing correlation between predicted and experimental logP. R²-squared=0.9581, adjusted R²: 0.9507, F-statistic: 130.7 on 25 and 143 DF, p-value: <2.2e-16, residual standard error: 0.457 on 143 degrees of freedom.

FIG. 6 is a graph showing average residuals (predicted logP-experimental logP) for training set by functional group.

FIG. 7 is a graph showing correlation between predicted and experimental logP for a set of compounds not included in the training set (i.e. external validation).

FIG. 8 is a graph showing root mean square error of prediction vs number of latent variables for PLS model of logP.

FIG. 9 is a graph showing predicted vs experimental log P values for the 140 compounds in the PLS model training set (5 latent variables, r²=0.954, RMSE: 0.438).

FIG. 10 is a graph showing predicted vs experimental log P values for 28 compounds in validation set predicted based on (a) MLR model (eq 6) q²ₑₓₜ=0.971, RMSEP: 0.537). (b) PLS model (q²ₑₓₜ=0.970, RMSEP=0.532).

FIGS. 11A-11B are graphs showing predicted vs experimental log Kₚ for (left panel) a group of compounds in the training set, and (right panel) a group of compounds not included in the training set (i.e. external validation).

FIGS. 12A-12C are graphs showing root mean square error of prediction vs number of latent variables for PLS model of log Kₚ.

FIGS. 13A-13B are graphs showing predicted vs experimental log Kₚ for (left panel) a group of compounds in the training set, and (right panel) a group of compounds not included in the training set (i.e. external validation).

FIGS. 14A-14C illustrate the standardized coefficients for the MLR and PLS reduced model (for log Kp) with cross terms.

### DETAILED DESCRIPTION

The present application describes methods of predicting chemical properties for a compound from experimental or predicted spectroscopic data. One or more chemical properties can be predicted using only spectroscopic data, such as NMR data (e.g., ¹H-NMR and/or ¹³C-NMR data). The methods are non-destructive of samples, do not require knowledge of chemical structure of the compound, and can be used with spectroscopic data recorded from pure compounds or from mixtures, or can be predicted for pure compounds of known chemical structures. The methods described in the present application can use experimental or predicted spectroscopic data to predict one or more chemical properties, for example, octanol-water partition coefficient (logP), skin permeability (log Kₚ), or other biologically or ecologically relevant property, such as oral bioavailability, skin sensitization, acute aquatic toxicity, chronic aquatic toxicity, aquatic bioaccumulation, or mutagenicity. Software implementing the method and a system for recording spectroscopic data and predicting chemical properties are also described.

As one example of a chemical property, the octanol-water partition coefficient (P, usually expressed as logP) can be important for predicting ability of chemicals (e.g., drugs, cosmetics and commodity chemicals) to enter the body. The value of logP is routinely determined for, e.g., drugs and commodity chemicals, either by experimental or through computational techniques. Experimental measurements of logP are tedious and require costly and time-consuming purification of the chemical. Computational prediction of logP via existing methods requires as input the exact chemical structure, which is sometimes not well defined or sometimes not known (for example in the case of a natural product extract or crude reaction mixture).

Methods for predicting logP are described that do not require purification of a chemical, or knowledge of an exact chemical structure. The methods use spectroscopic data, which is routinely collected during synthesis and characterization of chemical compounds. A mathematical algorithm uses a multivariate model to relate spectroscopic data to predict logP. The accuracy of the model can be comparable to or greater than current structural-based computational methods.

As another example of a chemical property, the skin permeation rate (Kₚ, often expressed as log Kₚ) can be important for predicting ability of chemicals (e.g., drugs, cosmetics and commodity chemicals) to enter the body via the skin. Experimental methods for testing skin permeability include in vitro diffusion chamber experiments, biomonitoring experiments for in vivo data and excised skin from human or animal sources, especially rat and pig. However, these methods are time-consuming and cost-prohibitive.

As for in silico predictions for log Kp, a number of quantitative structure-activity relationships (QSARs) that successfully relate skin permeability rate to chemical structures have been reported, although the predictive ability of some of these QSARs is limited to chemicals that are structurally similar to those used to build the model. Although chemical structure an important factor for log Kp, a number of additional factors also play a role, including the manner of application to the surface of the skin, the formulation, strategies that alter the barrier properties of the stratum corneum and a number of other biological factors.

Octanol-Water Partition Coefficient (logP)

The octanol-water partition coefficient (P, usually expressed as the logarithmic term, logP) is a physical/chemical property that is crucial for predicting the ability of compounds (e.g., commercial chemicals including drugs, cosmetics and commodity chemicals) to pass through biological membranes and enter the blood stream (i.e., bioavailability) (Leo, A.; Hansch, C.; Elkins, D. Chem Rev 1971, 71, 525). For example, medicinal chemists use logP to estimate the oral and skin bioavailability of drug candidates (Edwards, M. P.; Price, D. A. Annu Rep Med Chem 2010, 45, 381). The rules of thumb for oral bioavailability, called Lipinski rules, suggest that logP must be between 1 and 5 for a compound to be orally bioavailable to humans (Lipinski, C. A.; Lombardo, F.; Dominy, B. W.; Feeney, P. J. Advanced Drug Delivery Reviews 1997, 23, 3.) In addition to medicinal chemists, toxicologists and regulatory agencies also routinely use logP to predict the acute and chronic toxicity to aquatic species and potential for bioaccumulation. See e.g., Cronin, M. T. D. Curr Comput-Aid Drug 2006, 2, 405; Ellington, J. J.; Stancil, F. E.; U.S. Environmental Protection Agency, Environmental Research Laboratory: Athens, Ga., 1988; Kaiser, K. L.; Esterby, S. R. The Science of the total environment 1991, 109-110, 499; and Bintein, S.; Devillers, J.; Karcher, W. SAR and QSAR in environmental research 1993, 1, 29.

Rules of thumb for designing minimally toxic chemicals to aquatic species are also based on logP, among other parameters, and suggest that compounds with logP less than 2 are more likely to be safe to aquatic species (Voutchkova, A. M.; Kostal, J.; Steinfeld, J. B.; Emerson, J. W.; Brooks, B. W.; Anastas, P.; Zimmerman, B. Green Chemistry 2011, 13, 2373; Voutchkova-Kostal, A. M.; Kostal, J.; Connors, K. A.; Brooks, B. W.; Anastas, P. T.; Zimmerman, J. B. Green Chemistry 2012, 14, 1001; and Veith, G. D.; Call, D. J.; Brooke, L. T. Can J Fish Aquat Sci 1983, 40, 743). The octanol-water partition coefficient is thus a widely used property that is routinely determined by chemists, toxicologists and regulators. Streamlined methods for its determination are therefore desirable.

Experimental techniques for determining logP include the traditional shake-flask method, (Hansch, C.; Leo, A. J. Exploring QSAR: Fundamentals and Applications in Chemistry and Biology; American Chemical Society: Washington, DC, 1995) which requires extensive centrifugation; and newer methods involving HPLC (Haky, J. E.; Young, A. M. J Liq Chromatogr 1984, 7, 675.); micro-emulsion electrokinetic chromatography (Gluck, S. J.; Benko, M. H.; Hallberg, R. K.; Steele, K. P. J Chromatogr A 1996, 744, 141); and centrifugal partition chromatography (Menges, R. A.; Bertrand, G. L.; Armstrong, D. W. J Liq Chromatogr 1990, 13, 3061; and Berthod, A.; Han, Y. I.; Armstrong, D. W. J Liq Chromatogr 1988, 11, 1441). Some of the modern methods, such as multiple HPLC methods, microemulsion electrokinetic chromatography, and centrifugal partition chromatography can be more convenient than the shake flask method, but also limited to compounds with certain ranges of logP or pKa values, and are often less reliable than the shake-flask method (Danielsson, L. G.; Zhang, Y. H. Trac-Trend Anal Chem 1996, 15, 188). These methods are also poorly suited for some classes of compounds, such as surfactants. This is because surfactants form micelles, which affect the interactions with the solvents and chromatography columns. For example, the HPLC method for measurement of logP is invalid for surfactants because their retention times on the chromatography column are affected by the surfactant's preference for surfaces and interfaces (Wiggins, H.; Karcher, A.; Wilson, J. M.; Robb, I. In IPEC Conference 2008).

To provide a faster and more convenient method for logP determination, a number of in-silico estimation methods have been developed (Buchwald, P.; Bodor, N. Curr Med Chem 1998, 5, 353). Some predict logP by determining the relative contributions to logP from molecular fragments (group contribution methods), while others determine the atomic contributions. The predictive power of the most commonly used fragment and atom contribution tools, such as ALOGP, CLOGP, ACD, KOWWIN are in the range of 0.90-0.95 R² based on training sets of 6055-8364 compounds. See, e.g., Ghose, A. K.; Viswanadhan, V. N.; Wendoloski, J. J. Journal of Physical Chemistry A 1998, 102, 3762; Gombar, V. K.; Enslein, K. J Chem Inf Comp Sci 1996, 36, 1127; and Meylan, W. M.; Howard, P. H. J Pharm Sci 1995, 84, 83. Although very fast and accurate, these methods have limited applicability to structures containing predefined fragments, and do not take into account whole-molecule attributes, such as surface area, dipole moment and connectivity. More computationally expensive methods, such as Monte Carlo simulations, overcome the latter challenge (Jorgensen, W. L.; Briggs, J. M.; Contreras, M. L. J Phys Chem-Us 1990, 94, 1683; and Essex, J. W.; Reynolds, C. A.; Richards, W. G. J Am Chem Soc 1992, 114, 3634) but pose problems with parametrization (Dunn, W. J.; Nagy, P. I.; Collantes, E. R. J Am Chem Soc 1991, 113, 7898; and Dunn, W. J.; Nagy, P. I. J Comput Chem 1992, 13, 468). Linear solvation energy relationships have been used to provide a more rigorous treatment of solvation effects, but pose practical challenges for studies of novel molecules. Lastly, methods based on free energies of solvation in water and octanol (eq 1) show great promise but are computationally expensive, especially for large molecules (Delgado, E. J. Journal of Molecular Modeling 2010, 16, 1421.).

logK_{o/w}={ΔG₀^{s}(water)−ΔG₀^{s}(octanol)}/2.303RT (eq 1)

Although most of the methods discussed provide reasonably high accuracy, they all require knowledge of the exact chemical structure. This poses a challenge for the many compounds that exist as mixtures, such as surfactants and natural oils, as well as chemicals that contain fragments that were not defined in the training set.

Skin Permeability (Kᵣ)

Experimental methods for testing skin permeability include in vitro diffusion chamber experiments and biomonitoring experiments for in vivo data and excised skin from human or animal sources, especially rat and pig. (Katritzky, A. R.; Dobchev, D. A.; Fara, D. C.; Hur, E.; Tamm, K.; Kurunczi, L.; Karelson, M.; Varnek, A.; Solov'ev, V. P. J. Med. Chem. 2006, 49, 3305, which is incorporated by reference in its entirety) However, these methods are cost-prohibitive and time-consuming, and as a result accurate and fast predictive methods are highly desirable.

As for in silico predictions for log Kp, a number of quantitative structure-activity relationships (QSARs) that successfully relate skin permeability rate to chemical structures have been reported, although the predictive ability of some of these QSARs is limited to chemicals that are structurally similar to those used to build the model (see, e.g., Moss, G. P.; Dearden, J. C.; Patel, H.; Cronin, M. T. D. Toxicol. Vitro 2002, 16, 299, which is incorporated by reference in its entirety). These approaches relate experimentally measured percutaneous penetration of exogenous chemicals to physicochemical and structural descriptors derived from the chemical structures. For QSAR methods that were trained on more than 100 compounds the range of r² value is between 0.72-0.945. Although chemical structure is the primary factor for log Kp, a number of additional factors also play a role, including the manner of application to the surface of the skin, the formulation and strategies that alter the barrier properties of the stratum corneum and a number of other biological factors. However, in silico prediction studies commonly shows that hydrophobicity, reflected by octanol-water partition coefficient (log P), has been shown to have a substantial correlation with log Kp, while a number of QSARs share the generic form,

log Kp=a(Hydrophobicity)−b(Molecular Size)+c

See, e.g., Patel, H.; ten Berge, W.; Cronin, M. T. D. Chemosphere 2002, 48, 603; and Barratt, M. D. Toxicol. Vitro 1995, 9, 27, each of which is incorporated by reference in its entirety.

Although the relationship between the spectrometric data and the skin permeation rate may not be direct, the spectrometric data is often indicative of part of the chemical structure of the compound, and thus relevant to the skin permeation rate. Nonetheless, unlike traditional structure-based in silico methods, the presently described methods (a) do not require knowledge of exact structure and (b) are applicable to mixtures and formulations in addition to pure chemicals,

Prediction of Chemical Properties from Spectroscopic Data

A method of predicting a chemical property of a compound according to an embodiment of the current invention includes measuring or predicting spectroscopic properties of the compound and calculating a predicted value of the chemical property using a model representing the relationship between the experimental or predicted spectroscopic data and the chemical property.

The chemical property can be a physical-chemical property, e.g., one representing hydrophobicity or hydrophilicity of the compound. In some embodiments, the chemical property octanol/water partition coefficient (logP) or skin permeability (log Kₚ), but others may be used. The chemical property can be a biochemical property representing an interaction of the compound with living beings. Suitable biochemical properties include but are not limited to oral bioavailability, skin permeability, skin sensitization, acute aquatic toxicity, chronic aquatic toxicity, aquatic bioaccumulation, and mutagenicity.

The spectroscopic data can be NMR data, obtained by measuring or predicting a plurality of NMR resonances of the compound. The NMR resonances can be from one or more nuclei, including but not limited to ¹H, ¹³C, ¹⁵N, ¹⁹F, ²⁹Si and ³¹P. At least one molecular descriptor can be defined from the experimentally obtained or predicted NMR data. In defining the descriptor(s), one or more characteristics of each resonance can be considered, including but not limited to chemical shift, multiplicity, relative and/or absolute integration (corresponding to the number of protons associated with the resonance), and peak breadth (defined, for example, as peak width at half height).

Any suitable NMR spectrometer can be used to obtain experimental NMR data. Common NMR spectrometers include those operating at 30 or more MHz, e.g., in the range of 60 MHz to 900 or more MHz. Suitable NMR experiments are known in the art, and include without limitation liquid state (e.g., in solution of a suitable solvent) and solid state experiments; single-nucleus and correlated experiments; measurements of nuclear Overhauser effect; pulsed-field experiments; and others. Additional characteristics of resonances may be determined from such experiments.

A schematic depiction of an NMR spectrometer is shown in FIG. 2. A system 100 includes an NMR spectrometer which includes a magnet (105) for generating a static homogeneous magnetic field, and a probe (110) including RF coils (115) disposed within said homogeneous magnetic field. The RF coils (115) are configured to transmit a radio frequency magnetic pulse to a sample (120) including the compound. The RF coils (115) are also configured to measure a plurality of NMR resonances from the compound. The system also includes a data processor (125) operably connected to the NMR spectrometer. The data processor is configured to receive a plurality of NMR resonances of the compound; define at least one molecular descriptor of the compound based on the resonances; and calculate a predicted value of the chemical property based on the at least one molecular descriptor.

The molecular descriptor(s) can include plurality of different categories. The different categories can include, for example, resonances having a chemical shift within a given range and optionally having an absolute and/or relative integration in a given range. In one embodiment, the categories include chemical shift ranges spanning a total range, which can cover commonly occurring chemical shift values. For example, for ¹H NMR the categories can include chemical shift ranges spanning from at least about −6 ppm to at least about 15 ppm spectra; from at least about −5 ppm to at least about 14 ppm, or from at least about 0 ppm to at least about 12 ppm. Other chemical shift ranges will be appropriate for other nuclei, can span a range covering typical chemical shift values found for the nucleus in question. For example, for ¹³C NMR spectra, the chemical shift range can span from at least about 0 ppm to at least about 240 ppm. Additional categories may be used.

Thus, as an example, one category could be number of protons with resonances having a chemical shift between 1 ppm and 2 ppm; another category could be number of protons with resonances having a chemical shift between 2 ppm and 3 ppm; could be resonances having a chemical shift between 3 ppm and 4 ppm; and so on, or the intervals could be different (smaller, larger, and/or having different start and stop values). Other categories can be defined in terms of absolute and/or relative integration, multiplicity (e.g., doublet resonances, triplet resonances, and so on) or breadth (e.g., having a breadth above or below a given threshold). The categories can be defined in terms of a combination of characteristics, e.g., a category could be defined for resonances having a chemical shift within a defined range and having a breadth above a given threshold.

Defining the molecular descriptor(s) can include counting the number of resonances belonging to each of the plurality of different categories. Counting the number of resonances can include determining the absolute and/or relative integration of the resonance. In one embodiment, the descriptor can take the form of a value, table or matrix associating each measured resonance with one or more of the categories. In another embodiment, the descriptor can take the form of a value, table or matrix associating each category with the number of resonances having that category. In some embodiments, the descriptor is based only on spectroscopic data, e.g., characteristics of the measured resonances, such as ¹H resonances. Thus in some embodiments, the only information required to predict a chemical property of a compound is a ¹H NMR spectrum, a ¹³C NMR spectrum or both ¹H and ¹³C NMR spectra, and a model for calculating the predicted value based on that information. In other embodiments, the descriptor can include additional information. The additional information can include, for example molecular weight, or the total number of hydrogen and/or carbon atoms the compound contains

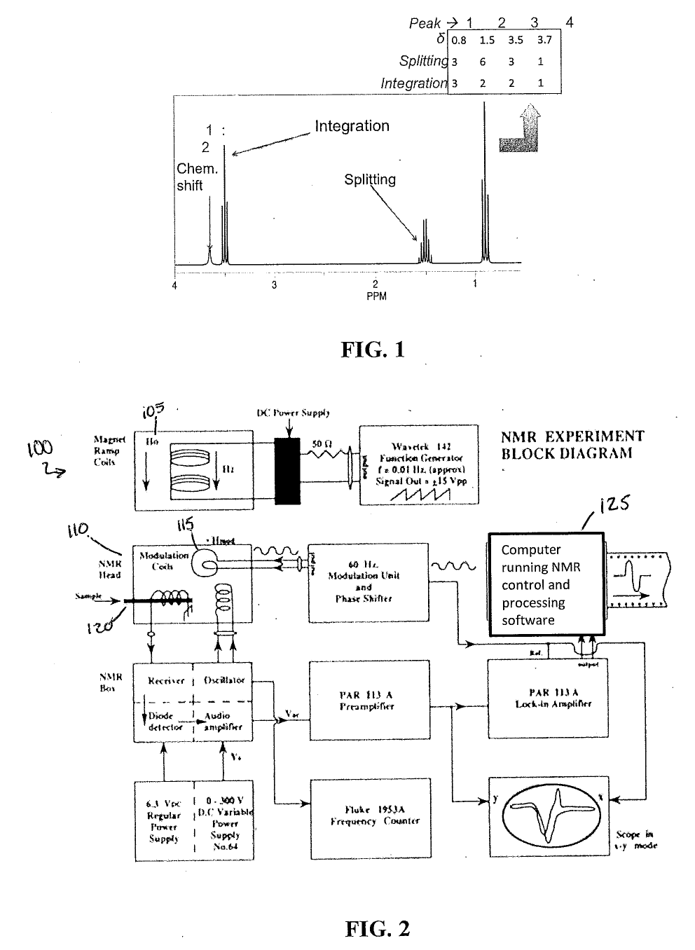

FIG. 1 illustrates a portion of an NMR spectrum of an example compound and a molecular descriptor defined from that spectrum. For each resonance, the characteristics of chemical shift (δ), multiplicity (splitting), and relative intensity (integration). In the example of FIG. 1, there are three protons counted in the chemical shift range of 0 to 1 ppm (i.e., the resonance with δ=0.8 has an integration of 3); two protons in the chemical shift range of 1 to 2 ppm (i.e., the resonance with δ=1.5 has an integration of 2); no protons in the chemical shift range of 2 to 3 ppm; and three protons in the chemical shift range of 3 to 4 ppm (i.e., the resonance with δ=3.5 has an integration of 2, and the resonance with δ=3.7 has an integration of 1). In other embodiments the molecular descriptor can include other information.

Once the molecular descriptor has been defined, it can be processed with a model that relates molecular descriptors to a predicted value of a chemical property. In one embodiment, the model can have the form:

$$Q = {\sum }_{i}^{j} {x}_{i} {n}_{i} + C$$

wherein Q is the predicted value of the chemical property, each nᵢ is the number of resonances counted in each category i, each xᵢ is a predetermined coefficient for category i,j is the total number of categories, and C is a predetermined constant. In other embodiments the model can consist of a non-linear regression, a neural network, a partial least squares model, a decision tree or a clustering-based model. Yet other embodiments can consist of support vector and machine learning approaches to relate the logP to the molecular descriptors obtained from NMR.

A model for predicting the value of a chemical property can be developed using a training set of compounds, e.g., a set of compounds for which the values of the desired chemical property are known and for which spectroscopic data is available. Molecular descriptors for each of the compounds of the training set are defined, and a model is determined correlating the predicted and known values of the property. Preferably, the correlation is high; for example, if the correlation is expressed as R², the model can have R² of 0.8 or greater; 0.85 or greater; 0.90 or greater; 0.95 or greater; 0.98 or greater; or 0.99 or greater.

In one embodiment the model has the form:

$$Q = {\sum }_{i}^{j} {x}_{i} {n}_{i} + C$$

wherein Q is the predicted value of the chemical property, each nᵢ is the number of resonances counted in each category i, each xᵢ is a predetermined coefficient for category i, j is the total number of categories, and C is a predetermined constant. In this embodiment, developing the model includes adjusting the coefficients xᵢ and constant C to give the best fit for correlation between the predicted and known values of the property. Developing the model can also include adjusting the number of categories i and the definitions of the categories. In developing the model, several different combinations of category definitions, number of categories, and corresponding coefficients may be tested, and the model giving the best fit for correlation between the predicted and known values of the property can be selected.

Thus a method for determining logP entirely from empirical spectroscopic data is provided. Nuclear Magnetic Resonance (NMR) data are routinely collected to characterize chemical structure after synthesis of a compound, and is widely applicable both to simple organic molecules and complex biological macromolecules. Advantageously, an NMR-based method for estimating logP is a non-destructive method that is readily incorporated into the synthesis and characterization workflow of new chemicals, eliminates the need to know the precise molecular structure, and is applicable to product mixtures, which commonly occur in commercial chemicals such as surfactants and plant extracts.

An example of an NMR system is illustrated in FIG. 2. A sample is placed in an NMR head, where it is subject to static homogeneous magnetic field H₀. The sample is also held in proximity to modulation coils and magnet ramp coils, which modify the magnetic field surrounding the sample. The modulation coils can provide an alternating field at a desired modulation frequency, controlled by a modulation unit and phase shifter.

The sample is also located to radiofrequency (RF) coils for transmitting a radio frequency magnetic pulse and detecting NMR signals. The radiofrequency pulses are produced with the use of various ancillary equipment, including for example, an oscillator, receiver, diode detector, audio amplifier, power supplies, preamplifier, frequency counter, lock-in amplifier, oscilloscope, or other equipment for producing, detecting, and/or processing of RF signals associated with NMR measurements.

The various components for conducting an NMR process—e.g., the modulation coils, RF coils, and ancillary equipment—can be controlled by a computer running NMR control and processing software. The control functions of the software operate the various components of the NMR system to record an NMR data (for example, an NMR spectrum) from the sample. The processing functions of the software compile, organize, and analyze the data, e.g., producing a visual depiction of the spectrum, or analyzing various features of the spectrum, such as determining numerical values for chemical shift, coupling, multiplicity, and integration of one or more resonances represented in the NMR data. The processing functions of the software can also compare, compile data and analyze data from multiple spectra, e.g., different spectra (e.g., ¹H and ¹³C spectra) recorded from the same sample, corresponding spectra from different samples (e.g., ¹H spectra from two or more samples), or different spectra from different samples (e.g., a ¹H spectrum from one or more samples, and a ¹³C spectrum from one or more different samples

The NMR system can be configured to perform a wide variety of NMR procedures, including but not limited to 1D NMR on nuclei such as ¹H, ¹³C, or ¹⁵N, continuous wave or Fourier transform NMR, 2D NMR on a combination of nuclei (e.g., ¹H and ¹³C; ¹H and ¹⁵N; or ¹³C and ¹⁵N), NOE procedures such as NOESY or HOESY procedures, and others.

The sample can be a solution of a sample material dissolved in a solvent, however, solid state samples can also be used in some configurations of the NMR system. The solvent can be chosen so as not to interfere with detection of resonances from the sample material (e.g., a deuterated solvent can be used when detecting ¹H resonances). A reference material can be included in the sample, to facilitate comparison of spectra recorded from different samples. The sample material can include a single pure compound, a single compound and low levels of impurities, an impure material such as a crude, unpurified reaction product, or a complex mixture of materials. In some cases, such as when a highly accurate spectrum is desired, it can be desirable that the sample includes a single pure compound, or a single compound and low levels of impurities. In other cases, the sample is desirably an impure material or complex mixture, for example, when it is desirable to avoid cumbersome sample purification prior to recording the NMR spectrum of the sample.

NMR data contains the majority of information needed to elucidate three dimensional structure for chemicals and the relative polarity and reactivity of each component atom (Willighagen, E. L.; Denissen, H.; Wehrens, R.; Buydens, L. M. C. Journal of Chemical Information and Modeling 2006, 46, 487). This information allows a quantitative model using only chemical shifts to be built. Structural information is encoded in NMR spectra in the form of chemical shift, integration, and multiplicity—all of which can be used as mathematical descriptors in regression models (FIG. 1). The essence of this model lies in the fact that lipophilicity can be estimated through several critical structural features of a molecule, such as carbon chain length, hydrocarbon unsaturation, number of hydrogen bond donors, and surface area. All of these parameters can be extracted from chemical shift, intensity, and multiplicity of each NMR-active nucleus (¹H and ¹³C are most relevant to organic compounds). For example, carbon chain length can be estimated through the absolute integration of the proton shifts present in the 0-2 ppm area of the ¹H-NMR spectrum. Hydrocarbon unsaturation can also be determined through peaks in specific NMR spectrum intervals, such as ranges 2-3 ppm, 5-6 ppm and 7-8 ppm. Some solvent interactions, such as hydrogen bond donors, can be detected by the breadth of proton NMR resonances in certain ranges. The number of protons responsible for the broad peaks in the NMR spectrum is indicative of the number of hydrogen bond donor groups present in the molecule (breadth is discussed in greater detail below). Finally, the chemical shift also informs the electron density of each atom in a molecule, and is reflected by the diamagnetic term of the chemical shift tensor.

### EXAMPLES

### Example 1

### logP

To develop a model for predicting logP from ¹H NMR data, a training set was built from experimental logP values of 165 compounds representing 20 functional classes (see FIG. 4), obtained from ECOSAR EpiSuite. Proton NMR spectra were predicted using Mestrec MNova NMR PredictDesktop v8 with CDCl₃ as solvent and 500 MHz magnetic field. NMR PredictDesktop uses two complementary methods for ¹H NMR prediction—increments methodology and the CHARGE program—and automatically selects the best proton prediction for each atom. The program has been validated and is considered to be one of most robust prediction tools on the market. The spectra were converted to [n x 4] matrices consisting of chemical shifts, splitting, integration and broadness for each of n proton resonances (FIG. 1), and were recorded in separate files. A script written in the R programming environment was used to generate a table of descriptors from these files, which reflects the number of protons that have resonances in discrete chemical shifts ranges. The script allowed optimization of the chemical shift ranges in a systematic manner. Multivariate linear models that relate experimental logP to the descriptors were then constructed in the R environment.

Multivariate linear regression (MLR) analyses were performed to fit the variables derived from NMR spectra to an equation of the following form:

$$log P = {\sum }_{i} {c}_{i} {x}_{i} + b$$

where cᵢ is the coefficient for each NMR-derived descriptor xᵢ.

The full set of descriptors were used to generate an initial MLR model, which was reduced in a stepwise manner based on the Akaike Information Criterion (AIC), which is a measure of relative quality of a statistical model, was used to compare different models. Internal validation consisted of (1) Leave One Out algorithm, where each compound is systematically excluded from the training set and its log P is predicted by the model, and (2) K-fold cross validation, where the data set is divided into K equal subsets and each is systematically excluded from the training set and used as a test set.

A Partial Least Squares (PLS) regression was selected because it is well-suited for data sets with a relatively large number of descriptors and leads to stable and highly predictive models, even when correlated descriptors are present. In brief, the method assumes that X is the descriptor matrix of dimensions [a×b], while Y[a] is the activity vector. The PLS regression reduces the large number of descriptors to a smaller number of orthogonal factors (latent variables). The latent variables are chosen to provide maximum correlation with the dependent variables, which allows the use of small number of factors in the final regression. X and Y are decomposed into a two-matrix product plus residuals:

X=TP′+E

Y=UQ′+F

where matrices E and F contain the residuals for X and Y; T and U are score matrices, and P′ and Q′ are loading matrices for X and Y respectively. The multiple regression model can be represented as:

Y=XB+G

where B is the matrix of regression coefficients.

The PLS regression was implemented in the R statistical environment.

The predictive power of each of the models was estimated using the coefficient of determination for predicted values of the validation set (q²ₑₓₜ) and the root mean square error of prediction.

Two well-established tools were used to obtain structure-based predictions of log P for the 168 compounds in the model. The first was Schrodinger's QikProp v. 3.0, a validated property prediction software utilized extensively in the field of drug discovery. The second benchmark method was KOWWIN (part of U.S. E. P. A.'s Estimation Program Interface Suite), a program that estimates the log P using an atom/fragment contribution method. The current KOWWIN model is based 13,058 compounds and is extensively used and reviewed.

A number of initial set of multivariate models was constructed using descriptors based on 5 to 24 spectral regions in the 0-12 ppm range. The initial linear regression was:

$$Log P = 0.248 {x}_{0 - 1} + 0.259 {x}_{1 - 2} - 0.042 {x}_{2 - 3} + 0.120 {x}_{3 - 4} + 0.528 {x}_{4 - 5} + 0.367 {x}_{5 - 6} + 0.557 {x}_{6 - 7} + 0.600 {x}_{7 - 8} - 0.106 {x}_{8 - 9} + 0.217 {x}_{9 - 10} - 0.120 {x}_{10 - 11} - 0.349 {x}_{11 - 12} - 0.35326$$

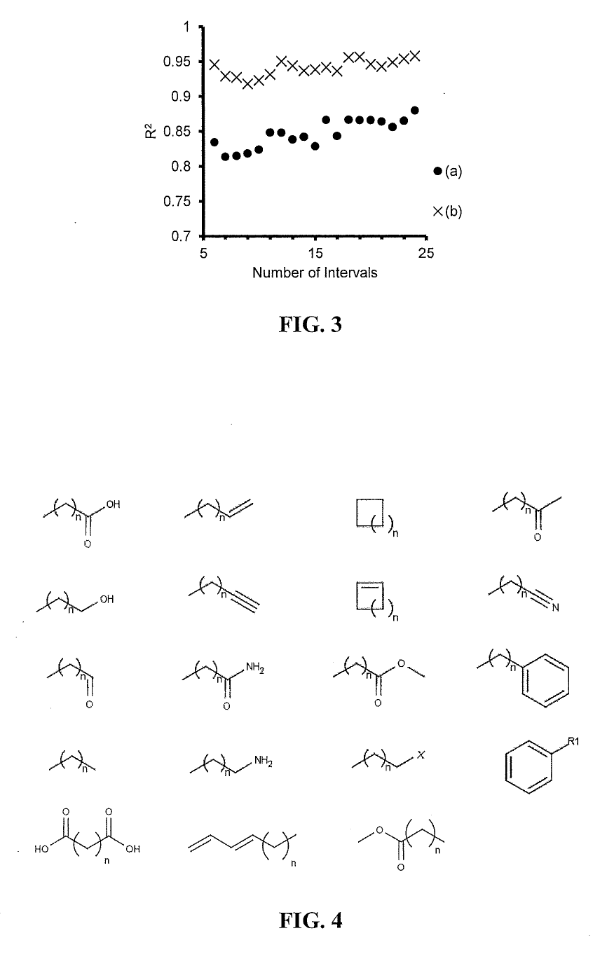

R²=0.861, df=116

where each xᵢ₋ⱼ was the number of protons that have chemical shifts between i and j ppm at 500 MHz. This simple model returned an R² value of 0.861, which was comparable to the accuracy of existing structure-based algorithms (0.82-0.98). The number of regions into which the spectrum was divided was optimized next. The number of regions (n) was varied from 6 to 24, and the accuracy of the model with each n was recorded. A positive relationship was observed between n and R² (FIG. 3). The best model at this stage was thus n of 24 regions, with an R² of 0.878.

A thorough analysis (Tables 1 and 2) of model performance by functional group indicated the need to better distinguish between amines, alcohols, alkyl halides and carboxylic acids. Chemical shift alone did not distinguish adequately between alkyl halides, amines and alcohols due to the proximity of the proton chemical shifts on the substituted carbon. Since these functional groups impart distinct lipophilicity, this affected the predictive power of the model. This model also did not take into account the effects of multiple hydroxyl and amine groups on logP, which are not additive—i.e. the marginal effects of each additional group decreases.

TABLE 1
Summary of leave one out (LOO) analysis of functional groups.

| | | # of | Degrees of |
|---|---|---|---|
| Left-out Functional Group | R² | Intervals | freedom |
| RCOOH | 0.855 | 8 | 108 |
| ROH | 0.924 | 10 | 98 |
| RCHO | 0.863 | 10 | 114 |
| Alkane | 0.877 | 10 | 110 |
| Alkene | 0.874 | 10 | 109 |
| Alkyne | 0.870 | 10 | 116 |
| RNH₂ | 0.879 | 10 | 111 |
| Cycloalkane | 0.871 | 10 | 114 |
| Cycloalkene | 0.868 | 10 | 118 |
| RX | 0.928 | 10 | 98 |
| Methyl Ether | 0.866 | 10 | 116 |
| Methyl Ketone | 0.866 | 10 | 110 |
| RCN | 0.863 | 10 | 111 |
| Phenyl Alkane | 0.754 | 9 | 106 |
| None | 0.868 | 10 | 119 |

TABLE 2
Summary of model performance by functional group.

| | | # of | Degrees of |
|---|---|---|---|
| Functional Group | R² | Intervals | freedom |
| RCOOH | 0.996 | 4 | 8 |
| ROH | 0.995 | 5 | 15 |
| Alkane | 0.933 | 1 | 7 |
| Alkene | 0.999 | 4 | 4 |
| RNH2 | 0.999 | 3 | 5 |
| Phenyl Alkane | 0.993 | 3 | 10 |
| Methyl Ketone | 0.997 | 3 | 5 |
| RCN | 0.999 | 5 | 2 |
| RX | 0.974 | 5 | 14 |

The model was refined to address both of these issues. A variable that accounted for the exchangeable protons (i.e., those that exhibit H/D exchange) improved the ability to distinguish between amines, alcohols and alkyl halides. Exchangable protons (sometimes referred to as acidic protons) exhibit broad peaks in ¹H-NMR and are thus readily identifiable as those with a width-at-half-height greater than 75 Hz. Groups that undergo H/D exchange, such as alcohols and amines, are slightly acidic and act as hydrogen bond donors, which accounts for their negative contribution to logP.

The broadness of a particular ¹H-NMR resonance depends on the rate of H/D exchange at that carbon. If the rate is sufficiently slow, two peaks will result. As it increases the peaks coalesce into one broad peak. The rate of proton exchange in amines, alcohols and carboxylic acids can be controlled with temperature and relaxation time of the NMR measurement. As a result, proton peak broadness can also be controlled and defined by a set of parameters. A “broad peak” was deemed to be one resulting from a measurement recorded at 23° C.-26° C. (room temperature) and having a width-at-half-height greater than 75 Hz and only two points that intercept the width-at-half-height line. The latter feature distinguished broad peaks from multiplets.

Three breadth variables were designated in distinct spectral regions. The number of intervals was re-analyzed and a general positive trend between number of intervals and R² was obtained (FIG. 3). The accuracy of the model with 24 intervals had an R² value of 0.956, showing that the inclusion of the additional broadness variables improved the logP prediction by distinguishing compounds that contain hydrogen bond donors of different strength.

The model generated by multivariate linear regression for 24 spectral regions showed excellent predictive power and is shown in the equation below, and Table 3 summarizes the statistics of the variable significance.

$$Log P = 0.203 {x}_{.5 - 1} + 0.258 {x}_{1 - 1.5} + 0.239 {x}_{1.5 - 2} - 0.07 {x}_{2 - 2.5} + 0.072 {x}_{2.5 - 3} + 0.042 {x}_{3 - 3.5} + 0.08 {x}_{3.5 - 4} + 0.016 {x}_{4 - 4.5} + 1.02 {x}_{4.5 - 5} + 0.231 {x}_{5 - 5.5} + 0.05 {x}_{5.5 - 6} + 0.280 {x}_{6 - 6.5} + 0.349 {x}_{6.5 - 7} + 0.454 {x}_{7 - 7.5} + 0.150 {x}_{7.5 - 8} - 0.019 {x}_{8 - 8.5} - 0.664 {x}_{9 - 9.5} - 0.061 {x}_{9.5 - 10} + 0.418 {x}_{10 - 10.5} + 0.925 {x}_{10.5 - 11} + 0.801 {x}_{11 - 11.5} + 1.888 {x}_{11.5 - 12} - 1.455 {x}_{BROAD} + 0.414$$

R²=0.949, df=144, Adjusted R-squared: 0.9412=, Residual standard error: 0.4986 F-statistic: 117.2, p-value: <2.2×10⁻¹⁶

TABLE 3
Summary statistics of variable significance of optimized model.
Descriptors X_{0-.5} and X_{8.5-9} returned
coefficients of 0 and were not included.

| | Estimate | Std. Error | t value | Pr(>\|t\|) |
|---|---|---|---|---|
| (Intercept) | 0.414241771 | 0.151226414 | 2.739215718 | 0.006937388 |
| X3 | 0.203670974 | 0.026865156 | 7.581231769 | 3.85E−12 |
| X4 | 0.258336608 | 0.008778839 | 29.42719641 | 8.85E−63 |
| X5 | 0.239456181 | 0.023789275 | 10.06571988 | 2.25E−18 |
| X6 | −0.069877984 | 0.032588828 | −2.144231255 | 0.03369315 |
| X7 | 0.072324737 | 0.06954903 | 1.039910078 | 0.300124577 |
| X8 | 0.042005553 | 0.049904043 | 0.841726437 | 0.401336795 |
| X9 | 0.080056055 | 0.057503462 | 1.392195404 | 0.166009523 |
| X10 | 0.016025837 | 0.117265045 | 0.136663378 | 0.89148776 |
| X11 | 1.021251157 | 0.191979668 | 5.31957976 | 3.89E−07 |
| X12 | 0.231464045 | 0.092104929 | 2.51304732 | 0.013070868 |
| X13 | 0.049977537 | 0.11430509 | 0.43722932 | 0.662600051 |
| X14 | 0.280434295 | 0.190916429 | 1.468885079 | 0.144045154 |
| X15 | 0.348893166 | 0.108543712 | 3.21431025 | 0.001614108 |
| X16 | 0.454113357 | 0.033807971 | 13.4321387 | 3.54E−27 |
| X17 | 0.149518282 | 0.081290637 | 1.839305083 | 0.067929867 |
| X18 | −0.017885141 | 0.140677948 | −0.127135357 | 0.899010627 |
| X20 | −0.664241771 | 0.521014395 | −1.274900995 | 0.204397515 |
| X21 | −0.06084763 | 0.177875429 | −0.342080016 | 0.732789421 |
| X22 | 0.418413868 | 0.408858588 | 1.023370622 | 0.307848761 |
| X23 | 0.924945649 | 0.138455701 | 6.680444648 | 4.83E−10 |
| X24 | 0.800891109 | 0.268501274 | 2.982820523 | 0.003355355 |
| X25 | 1.888801063 | 0.577679713 | 3.269633709 | 0.001347169 |
| X26 | −1.455017547 | 0.103556665 | −14.05044812 | 8.80E−29 |

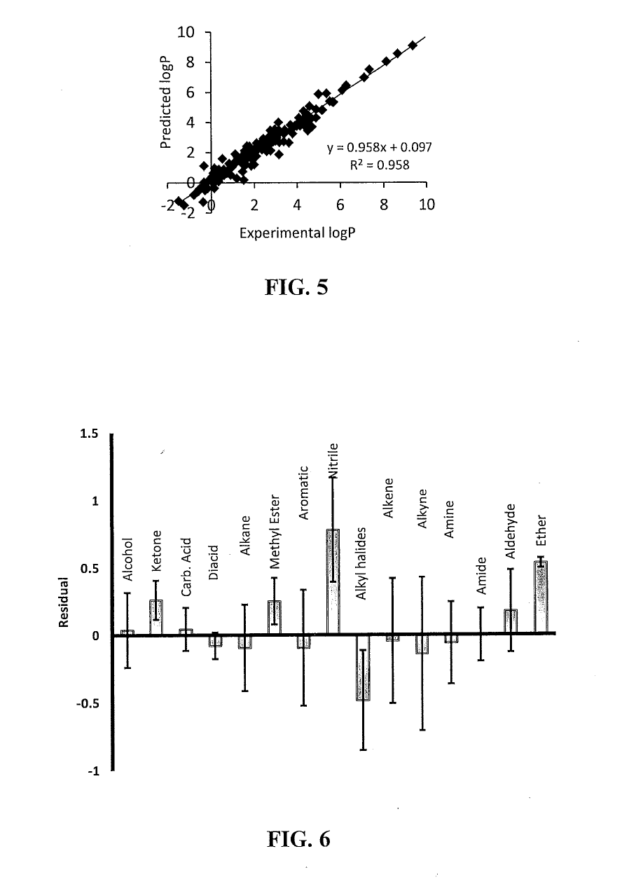

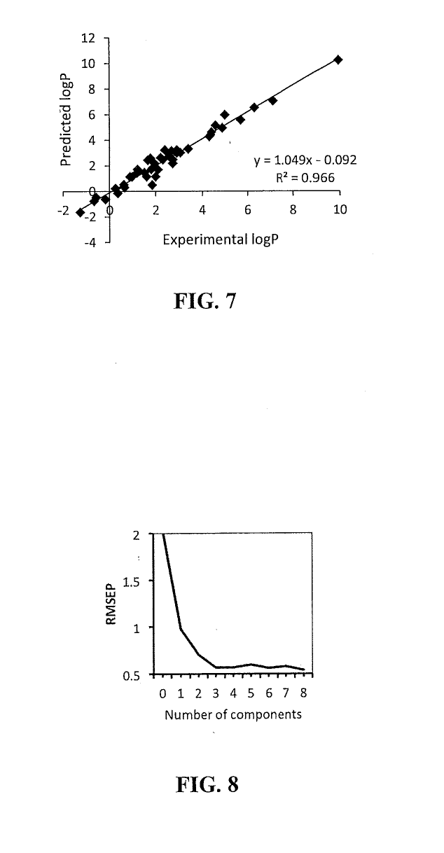

An analysis of the predictive power of the model by functional group indicates that nitriles and alkynes had the highest residuals (FIGS. 5-7). Where other functional groups have protons with distinctive chemical shifts (e.g., vinyl, hydroxyl, aryl), nitrile and internal alkyne groups lack such protons. Inclusion of ¹³C-NMR spectral data can help distinguish such functional groups and increase the predictive power of the model.

To reduce this initial model we applied an iterative stepwise procedure based on minimization of AIC values. The AIC provides a useful way to balance the number of variables with the goodness of fit of the reduced model. See O. A. Raevsky, K. J. Schaper, J. K. Seydel, Quant. Struct-Act. Relat. 1995, 14 (5), 433-436, which is incorporated by reference in its entirety. This procedure eliminated 15 of the variables, yielding a final model with 13 variables. This final model is described in the following equation, where xᵢ corresponds to the consecutive parameters obtained from absolute integrations of the spectral regions, and bₙ to the three broadness parameters. The model fits the Trophsa, Gramatica and Gombar criterion for ratio of number of descriptors to number of data points. See A. Tropsha, P. Gramatica, V. K. Gombar, QSAR & Comb. Sci. 2003, 22 (1), 69-77, which is incorporated by reference in its entirety.

logP=0.229x_{0.5}+0.259x₁0.234x_{1.5}−0.074x_{2+0.516}x_{4.5}+0.322x₅+0.407x_{5.5}+0.381x_{6.5}+0.476x₇+0.270x_{7.5}−1.494b₁−2.198b₂−0.538b₃+0.390

r²=0.949, r²_{adj}=0.943, n=140, F=179.4, p-value: <2.2×10⁻¹⁶, RMSE: 0.481.

K-fold cross validation (K=10) was performed to internally validate the model. This involves dividing the data set into K subsets, and using each in turn to test the predictive power of a model built from the remaining data set. The average q² of 10-fold cross validation was 0.944, with mean root square error (rmse) of 0.551. A leave-one-out (LOO) cross validation was also performed, which yielded a q²_{LOO} of 0.946 and RMSE of 0.550. These metrics indicate that the model shows consistent predictive power and robustness. Furthermore, the residuals were randomly distributed for the predicted log P values.

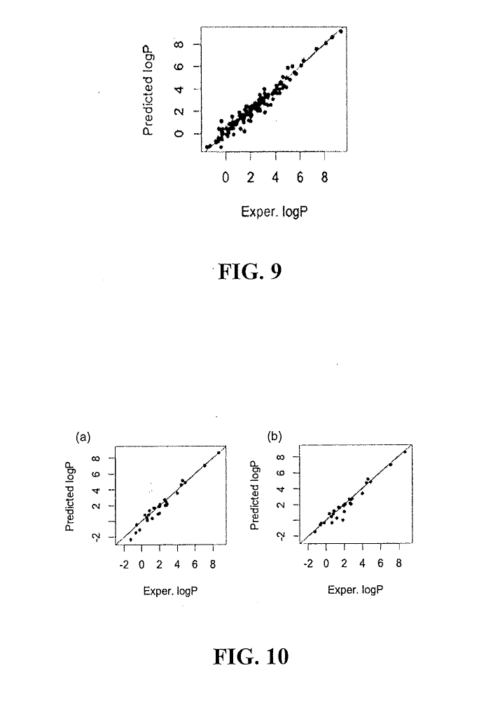

In preparation for generating the PLS model the descriptors were scaled and centered. The number of significant latent variables was determined by the cross-validation method, which optimizes the residual standard error by the leave-one-out method. As shown in FIG. 8, the number of latent variables that yields the lowest root mean square error of prediction was five. The five latent variables explain 95.39% of the variance in the Y matrix (log P) and 46.55% of the variance in the X matrix (set of descriptors). FIG. 9 shows the fit between the predicted and experimental log P values of the 140 compounds in the training set. The RMSE for this model is slightly lower than that of the MLR model (0.438 vs 0.481). The residuals of the compounds in the training set showed no pattern with the predicted log P value.

The relationship between each descriptor used in the two models and the experimental log P values was analyzed to obtain a rational understanding of their predictive ability. The relevance of the variables in the both models was compared based on the standardized coefficients (FIG. 9). The most relevant descriptors for both models were found to consistent, and included the number of protons that resonate between 0.5-2, 4.5-5.5, 6.5-8 ppm and the three descriptors associated with peak broadness.

The descriptors that correspond to resonance between 0.5-2 ppm are associated with strongly lipophilic structural motifs, such as aliphatic chains. Resonances between 4.5-5.5 ppm are associated with protons proximal to electron withdrawing groups, such as hydroxyls, halogens and amines, which contribute to the hydrophilicity of the molecule. Resonances in the 6.5-8 ppm range are associated with protons on aromatic rings, which have a distinct contribution to hydrophobicity.

The broadness descriptors were important to both models. The inclusion of broadness descriptors to both models significantly reduced the average residuals of compounds containing amino, hydroxyl, alkyl halide and carboxylic acid groups. These three descriptors identify protons involved in H/D exchange in deuterated solvents. H/D exchange can be detected in ¹H NMR spectra as broad peaks (width-at-half-height greater than ˜75 Hz). Given that broadness also depends on concentration, pH and solvent, these factors must be controlled in spectral collection. Functional groups that exhibit H/D exchange, such as alcohols and amines, participate in hydrogen bonding (electrostatic intermolecular interactions exhibited by molecules containing hydrogen atoms bound to N, O or F). Hydrogen bonding increases water solubility and thus has a negative contribution to log P. See R. Gozalbes, J. P. Doucet, F. Derouin, Curr. Drug Target 2002, 2, 93-102, which is incorporated by reference in its entirety.

The predictive power of the MLR and PLS models on the same test set were compared, as shown in FIG. 10 and Table 4. The maximum absolute residuals for the MLR model was 1.84 log units, compared to 1.04 for the PLS model, on a data set with experimental log P values in the range of −1.51 to 9.95. The external validation subset was resampled 10 times from the 168-compound data set to check the consistency of both models. The average RMSEP for the MLR model was 0.540, while that for the PLS model: 0.531.

TABLE 4
Statistical model parameters obtained from MLR and PLS models.

| Parameter | MLR | PLS |
|---|---|---|
| r² | 0.949 | 0.954 |
| RMSE | 0.484 | 0.438 |
| q²ₑₓₜ | 0.971 | 0.970 |
| RMSEP | 0.537 | 0.532 |
| Number of | — | 5 |
| latent | | |
| variables | | |
| Number of | 13 | — |
| descriptors | | |

These data indicate that although the predictive performance of the two models was closely comparable, that of the PLS model was slightly superior and more stable than the MLR model. However, this may change as the training set for the models is expanded to include greater structural diversity, which will populate the any descriptor space that is not utilized in this model, such as resonances between 8.0-8.5 ppm.

An analysis of predictive ability by functional class indicated that nitriles and alkynes (especially internal) had the highest residuals. This was attributed to the lack of protons on the sp-hybridized carbons, which hindered the ability of the model to identify these functional groups. This issue can be addressed by the inclusion of ¹³C-NMR spectral data.

The applicability domain for this model can be conservatively defined by the structural diversity and defining properties of the training set. As such, the applicability domain for this model consists of compounds with molecular weight <450 Da, which have the functional groups that are present in the training set, and have no more than 3 functional groups per molecule.

The performance of the model was compared to two well-established methods for structure-based prediction: Schrodinger's QikProp and EPI Suite KOWWIN (see W. J. Jorgensen, QikProp, v. 3.0; Schrodinger, LLC: New York, N.Y., 2003; and US EPA. 2013 Estimation Programs Interface Suite™ for Microsoft® Windows, v 4.11. United States Environmental Protection Agency, Washington, D.C., USA, each of which is incorporated by reference in its entirety). The log P values of the 28 compounds in the external validation set were predicted with both programs. KOWWIN-predicted log P values showed the highest correlation to experimental data (r²=0.987, RMSE=0.234), while those from Qikprop: r²=0.959, RMSE: 0.421. The predictions obtained from our model compared well to both of the structure-based tools (r²=0.970, residual standard error: 0.532). We note, however, that both of the commercial packages used have been trained on substantially larger training sets, and anticipate that expansion of the training set will yield RMSEP values that are even more favorably comparable with structure-based models.

### Example 2

### Skin Permeability

The range of the experimental value of log Kp of for 143 known compounds selected for study from −9.66 to −3.36. The data were randomly split into a training set with 113 compounds and a test set with 30 compounds. Only the training set was used in the model building process and the test set was used in the validation part.

Proton NMR spectra were predicted using MNova NMR Predict v8 with CDCl₃ as solvent and a 500 MHz magnetic field. The spectra were converted into [nx3] matrices, where n is the number of distinct resonances. The matrices contain chemical shifts, integration and broadness (width at half height) for each of n ¹H and ¹³C resonances (FIG. 1, which illustrates only ¹H resonances for clarity). A script in the R environment was used to generate a set of descriptors for each compound, which correspond to the number of hydrogen and carbon atoms with resonances in discrete chemical shifts ranges. For example, one descriptor corresponds to the number of protons in the 0-1 ppm bin on a 500 MHz instrument. The spectrum of 1-12 ppm was thus initially split into 24 bins to generate the model. The Carbon NMR spectra were processed in a similar way, and 25 descriptors were generated.

Multivariate linear regression (MLR) analyses were performed to fit the variables derived from NMR spectra to an equation of the following faun:

$$log {K}_{p} = {\sum }_{i} {c}_{i} {x}_{i} + b$$

where cᵢ is the coefficient for each NMR-derived descriptor xᵢ.

The first model employed all NMR descriptors as X variables. Molecular weight was added to the list of descriptors after the original model was built. The comparison between the two models was made and the one with better R² was chosen to perform variable reduction. The model underwent a stepwise calculation using the Akaike Information Criterion (AIC) to put the model in its most possibly reduced form.

Cross terms were also added to the descriptors to increase the predictability of the model. The pair of multiplied descriptors that gave the model best improvement was chosen and added in the final model. This process was repeated several times and a total of 6 cross terms were generated and used in the final model.

Both internal and external validations were carried out. For internal validation, leave-one-out (LOO) and K-fold cross validation were the two techniques used and the standard root mean square error (RMSE) of estimates for predicted log Kp were calculated. Both techniques employed the same mechanism of dividing the training set into a number of subsets, and taking one subset out as the test set while building the model from the rest (In LOO, every compound is a subset). For external validation, the log Kp values of the test set of the 30 compounds that were chosen earlier were predicted by the final model and Q² calculated.

The partial least square analysis was carried out to compensate for the challenges of multilinear regression model to accommodate to relatively large number of descriptors and correlation between the descriptors. The ‘pls’ package was used in R to establish the optimal PLS model. The log Kp percent of variance explained and its corresponding number of X latent variables was the primary factor to consider in model building. Based on prior result from MLR model, molecular weight was included in the decriptor since it provided a significant boost to the overall predictability of the model.

Since the number of descriptors was no longer a concern in PLS model, both the full model and the best reduced model from the MLR analysis were examined using the PLS formula. The number of X latent variables was picked if it provided the best RMSE and relatively good prediction of log Kp. The results of both models were obtained. Finally, external validation was implemented on both models in the same way as on the MLR models.

Using the full set of descriptors without molecular weight yielded an adjusted R² of 0.6708 (for simplicity, all R² from now on are the adjusted R²). With molecular weight the model's R² improved to 0.7529. The huge increase in R² set down the town and all subsequent results would have molecular weight in the descriptors. Under this decision, the full model had a total of 53 descriptors. After going through AIC variable selection, the optimal number of descriptors was fixed at 31. To increase the predictability of the model, 6 pairs of cross terms were incorporated in the reduced model, making the final number of descriptors at 37. These 6 cross teuiis were: H2×H7, H2×C90, H6×C10, C110×C120, H5×C50, Br.0-4×C100. The final model had a R² of 0.8364.

The LOO validation gave a RMSE of 0.6557 and the 10-fold cross validation had 0.7239 for this parameter. For external validation, the predictive Q² for the test set was 0.8412 (see FIGS. 11A and 11B).

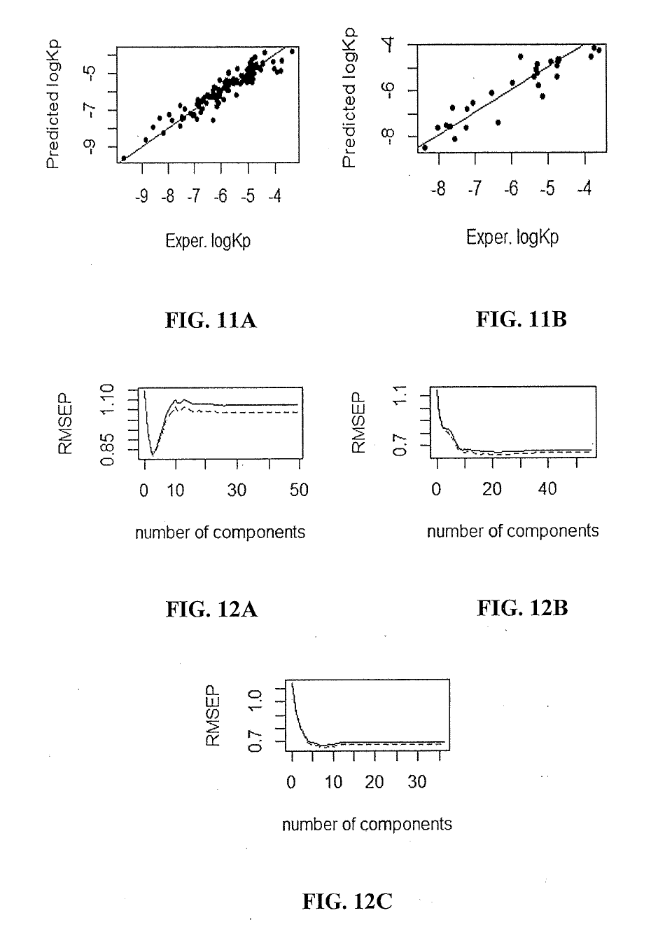

The RMSE of both the full and reduced PLS models with (or without) cross terms is given below in figures. Based on the graph, the optimal number of X latent variables for the full model without cross terms was at n=3 with 69.97% of log Kp explained (FIG. 12A). The number for the full model with cross terms was n=22 and 93.63% explained (FIG. 12B). For the reduced model with cross terms, n=8 and 87.26% of log Kp was explained (FIG. 12C).

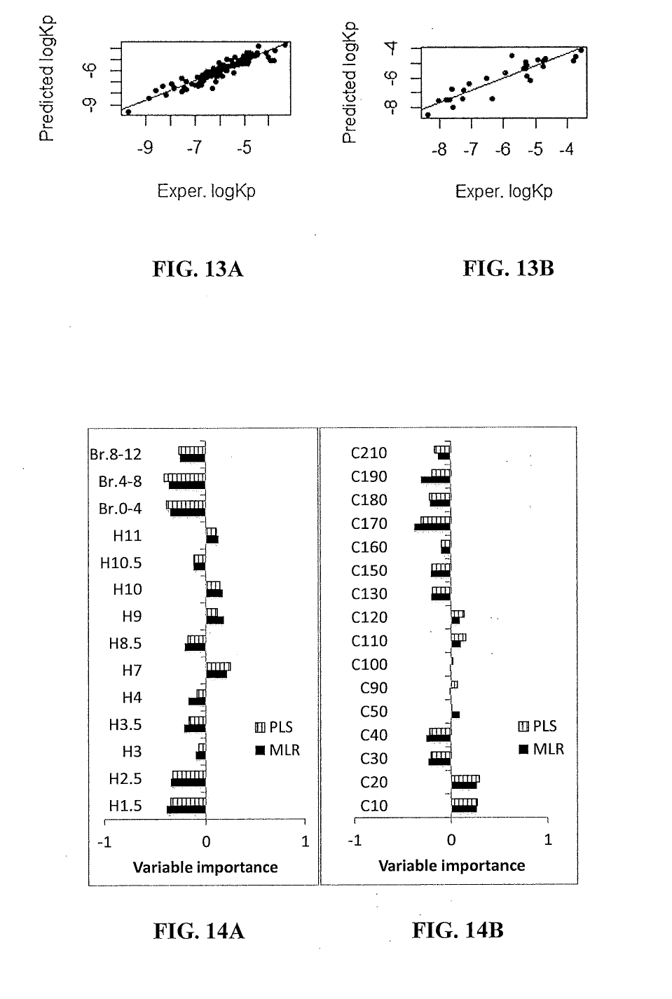

In this particular case, of the models tested, the optimal result came from the reduced model with cross terms. The other models were discarded since they could not either provide a good percent of log Kp explained, or required too many number of components to reach its optimal RMSE. Therefore, external validation was only implemented reduced models with cross terms with the optimal number of X latent variables picked at n=8. The Q² for the test set was 0.834 (see FIGS. 13A-13B).

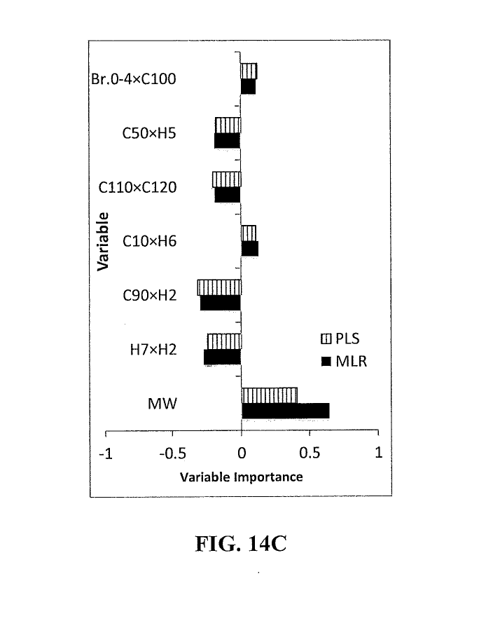

Lastly, FIGS. 14A-14C give the standardized coefficients for the MLR and PLS reduced model with cross terms (with two significant digits).

The embodiments illustrated and discussed in this specification are intended only to teach those skilled in the art the best way known to the inventors to make and use the invention. Nothing in this specification should be considered as limiting the scope of the present invention. All examples presented are representative and non-limiting. The above-described embodiments of the invention may be modified or varied, without departing from the invention, as appreciated by those skilled in the art in light of the above teachings. It is therefore to be understood that, within the scope of the claims and their equivalents, the invention may be practiced otherwise than as specifically described.

What is claimed is:

1. A method of predicting a chemical property of a compound, comprising:
measuring and/or predicting a plurality of NMR resonances of the compound;
defining at least one molecular descriptor of the compound based on the measured and/or predicted resonances; and
calculating a predicted value of the chemical property based on the at least one molecular descriptor.

2. The method of claim 1, wherein the at least one molecular descriptor includes the number of resonances belonging to each of a plurality of different categories.

3. The method of claim 2, wherein the plurality of different categories includes at least one of:
a category of resonances having a chemical shift in a predetermined range, and optionally having an absolute and/or relative integration in a predetermined range;
a category of resonances having a peak breadth above a predetermined threshold; and
a category of resonances having a predetermined multiplicity.

4. The method of claim 2, wherein the plurality of different categories includes a plurality of categories of resonances having a chemical shift in a plurality of different predetermined ranges.

5. The method of claim 4, wherein the plurality of different categories further includes a category of resonances having a breadth above a predetermined threshold.

6. The method of claim 1, wherein the NMR resonances include ¹H-NMR and/or ¹³C-NMR resonances.

7. The method of claim 5, wherein the plurality of different categories include the number of ¹H-NMR resonances in each of a plurality of predetermined ranges of chemical shift spanning from at least 0 ppm to at least 12 ppm.

8. The method of claim 5, wherein the plurality of categories include the number of ¹³C-NMR resonances in each of a plurality of predetermined ranges of chemical shift spanning from at least 0 ppm to at least 240 ppm.

9. The method of claim 1, wherein the chemical property is selected from: octanol-water partition coefficient (logP); skin permeability (log Kₚ); oral bioavailability; skin sensitization; acute aquatic toxicity; chronic aquatic toxicity; aquatic bioaccumulation; and
mutagenicity.

10. The method of claim 1, wherein the chemical property is octanol-water partition coefficient (logP) or skin permeability (log Kₚ).

11. The method of claim 1, wherein calculating the predicted value includes using a model having the form:
$$Q = {\sum }_{i}^{j} {x}_{i} {n}_{i} + C$$
wherein Q is the predicted value, each n, is the number of resonances counted in each category i, each xᵢ is a predetermined coefficient for category i,j is the total number of categories, and C is a predetermined constant.

12. The method of claim 11, wherein the at least one molecular descriptor is based only on the measured and/or predicted resonances, wherein the resonances are ¹H resonances, ¹³C resonances, or both ¹H and ¹³C resonances.

13. The method of claim 12, wherein the model has a correlation coefficient R² of 0.95 or greater between the predicted values Q and experimentally determined values of the chemical property.

14. The method of claim 13, wherein the property is logP and the model is:
log P=0.229x_{0.5}+0.259x₁+0.234x_{1.5}−0.074x₂+0.516x_{4.5}+0.322x₅+0.407x_{5.5}+0.381x_{6.5}+0.476x₇+0.270x_{7.5}−1.494b₁−2.198b₂−0.538b₃+0.390.

15. A method of building a model for predicting a chemical property comprising:
(a) measuring and/or predicting a plurality of NMR resonances of a plurality of compounds belonging to a training set of compounds;
(b) defining at least one molecular descriptor of each compound belonging to the training set based on the measured and/or predicted resonances of that compound;
(c) calculating a predicted value of the chemical property for each compound belonging to the training set based on the at least one molecular descriptor;
(d) for each compound belonging to the training set, comparing the predicted values of the chemical property to experimentally determined values of the chemical property, and determining a correlation coefficient between the predicted values of the chemical property to experimentally determined values of the chemical property;
(e) optionally redefining the at least one molecular descriptor; and
(f) repeating steps (b)-(e) to identify a set of molecular descriptors providing a desired correlation coefficient.

16. The method of claim 15, wherein the at least one molecular descriptor includes the number of resonances belonging to each of a plurality of different categories including at least one of:
a category of resonances having a chemical shift in a predetermined range, and optionally having an absolute and/or relative integration in a predetermined range;
a category of resonances having a peak breadth above a predetermined threshold; and
a category of resonances having a predetermined multiplicity.

17. The method of claim 15, wherein the at least one molecular descriptor is based only on the measured and/or predicted resonances, wherein the resonances are ¹H resonances, ¹³C resonances, or both ¹H and ¹³C resonances.

18. A computer-readable medium for predicting a chemical property of a compound, comprising non-transitory computer-executable code which, when executed by a computer, causes the computer to:
receive a plurality of NMR resonances of the compound;
define at least one molecular descriptor of the compound based on the resonances; and
calculate a predicted value of the chemical property based on the at least one molecular descriptor.

19. A system (100) for predicting a chemical property of a compound, comprising:
an NMR spectrometer including:
a magnet (105) for generating a static homogeneous magnetic field; and
a probe (110) including RF coils (115) disposed within said homogeneous magnetic field, wherein the RF coils (115) are configured to transmit a radio frequency magnetic pulse to a sample (120) including the compound, and wherein the RF coils (115) are configured to measure a plurality of NMR resonances from the compound; and
a data processor (125) operably connected to the NMR spectrometer, wherein said data processor is configured to:
receive a plurality of NMR resonances of the compound;
define at least one molecular descriptor of the compound based on the resonances; and
calculate a predicted value of the chemical property based on the at least one molecular descriptor.

20. The system of claim 19, wherein the system is configured to at least measure ¹H NMR resonances, ¹³C NMR resonances, or both ¹H and ¹³C NMR resonances.
